(19) United States
(12) Patent Application Publication
(10) Pub. No.: US 2026/0351553 A1
(43) Pub. Date: Nov. 5, 2026

(54) METHOD FOR MANUFACTURING LITHIUM ION SECONDARY BATTERY

(71) Applicant: Prime Planet Energy & Solutions, Inc., Tokyo (JP)

(72) Inventors: Rutsu TAMURA, Kobe-shi (JP); Yuma KAMIYAMA, Osaka-shi (JP)

(21) Appl. No.: 19/657,002

(22) Filed: Apr. 24, 2026

(30) Foreign Application Priority Data
Apr. 30, 2025 (JP) 2025-075083

(51) Int. Cl. H01M 4/04; G01R 31/389; G01R 31/52; H01M 10/0525

(52) U.S. Cl. CPC H01M 4/0445; G01R 31/389; G01R 31/52; H01M 10/0525

(57) ABSTRACT

It is an object of the present disclosure to provide a method for manufacturing a lithium ion secondary battery in which precipitation of lithium metal on the negative electrode surface is suppressed. The technology disclosed herein includes a battery assembly preparing step of preparing a battery assembly composed of a case containing an electrode body and a nonaqueous electrolyte; a first charging step of charging the battery assembly; a first aging step of subjecting the battery assembly to aging treatment after the first charging step; and a second charging step of charging the battery assembly after the first aging step until the state of charge (SOC) of the battery assembly reaches 100%. Here, in the second charging step, the battery assembly is charged such that the Li saturation degree of the negative electrode surface is 0.98 or less.

### CROSS REFERENCE TO RELATED APPLICATION

This application claims the benefit of priority to Japanese Patent Application No. 2025-075083 filed on Apr. 30, 2025. The entire contents of this application are hereby incorporated herein by reference.

### BACKGROUND OF THE DISCLOSURE

### 1. Field

The present disclosure relates to a method for manufacturing a lithium ion secondary battery.

### 2. Background

In typical manufacturing of a lithium ion secondary battery, a battery assembly including a case containing an electrode body and a nonaqueous electrolyte is prepared, and the battery assembly is subjected to initial charging and aging. The manufacturing of a lithium ion secondary battery is required to shorten the charging time by charging the battery assembly with a large current (high rate) from the viewpoint of production efficiency. For example, Japanese Patent Publication No. 2019-121556 discloses an initial charging method for a lithium ion secondary battery by performing initial charging by 2 stages of a film formation period and a charging period, wherein in the film formation period, charging is performed by CCCV charging at a current rate of 5 C or less while stepwise increasing the target voltage, and in the charging period, charging is performed by CCCV charging at a current rate of higher than 5 C and 6.5 C or less until the lithium ion secondary battery is fully charged.

### SUMMARY

In charging of a lithium ion secondary battery such that the state of charge (SOC) reaches to 100% (full charge) for the first time, volume expansion of the negative electrode active material due to occlusion of lithium ions is likely to occur. Accordingly, when charging is performed at a high rate in the initial full charging, a crack or peeling may occur in the negative electrode active material by the volume expansion of a negative electrode active material. Consequently, a new surface of the negative electrode active material is generated. Such a new surface deteriorates the lithium ion-accepting properties of the negative electrode active material, and consequently, lithium metal may precipitate on the negative electrode surface.

The present disclosure has been made in consideration of the above circumstances, and the main purpose thereof is to provide a method for manufacturing a lithium ion secondary battery in which precipitation of lithium metal on a negative electrode surface is suppressed.

The technology disclosed here is a method for manufacturing a lithium ion secondary battery including an electrode body in which a positive electrode and a negative electrode containing a negative electrode active material are laminated with a separator therebetween and including a nonaqueous electrolyte. The method includes a battery assembly preparing step of preparing a battery assembly composed of a case containing the electrode body and the nonaqueous electrolyte, a first charging step of charging the battery assembly, a first aging step of subjecting the battery assembly to aging treatment after the first charging step, and a second charging step of charging the battery assembly after the first aging step until the state of charge (SOC) of the battery assembly reaches 100%. In the second charging step, the battery assembly is charged such that the Li saturation degree of the negative electrode surface is 0.98 or less.

According to such a formation, a lithium ion secondary battery in which precipitation of lithium metal on the negative electrode surface is suppressed can be manufactured.

### BRIEF DESCRIPTION OF THE DRAWINGS

FIG. 1 is a perspective view schematically illustrating a lithium ion secondary battery according to an embodiment;

FIG. 2 is a schematic cross-sectional view taken along the line II-II in FIG. 1:

FIG. 3 is a schematic view illustrating a structure of an electrode body according to an embodiment;

FIG. 4 is a flow diagram of a method for manufacturing a lithium ion secondary battery according to an embodiment;

FIG. 5 is a diagram schematically illustrating transfer of lithium ions in the negative electrode of a battery assembly;

FIG. 6 is a graph showing the SOC (50% to 100%) of the battery assembly in the second charging step and changes in the current value during charging according to a first embodiment;

FIG. 7 is a diagram schematically illustrating transfer of lithium ions in the negative electrode of a battery assembly in the second charging step according to a second embodiment;

FIG. 8 is a graph showing the SOC (50% to 100%) of the battery assembly in the second charging step and changes in the current value during charging according to the second embodiment;

FIG. 9 is a photograph of an electrode body (negative electrode) showing the result of evaluation of lithium metal precipitation in Example; and

FIG. 10 is a photograph of an electrode body (negative electrode) showing the result of evaluation of lithium metal precipitation in Comparative Example.

### DETAILED DESCRIPTION OF THE PREFERRED EMBODIMENTS

Some preferable embodiments of the present disclosure will now be described with reference to the drawings as appropriate. Matters that are other than those specifically mentioned in the present specification but are necessary for implementing the present disclosure (for example, general configuration and manufacturing process that do not characterize the lithium ion secondary battery of the present disclosure) can be grasped as design items by those skilled in the art based on the prior art in the field. The present disclosure can be implemented based on the contents disclosed in the present specification and common technical knowledge in the field.

In the following drawings, the same symbols are used for members and parts that perform the same function, and duplicated explanation may be omitted or simplified. In the present specification, the expression “A to B” indicating a range encompasses a meaning of “greater than A and less than B” as well as a meaning of A or more and B or less.

In the description below, the symbols L, R, F, Rr, U, and D in the drawings represent left, right, front, rear, up, and down, respectively. The symbols X, Y, and Z in the drawings represent the short side direction of a lithium ion secondary battery 100, the long side direction orthogonal to the short side direction, and the vertical direction (also referred to as height direction) orthogonal to the short side direction and the long side direction, respectively. However, these directions are defined for convenience of explanation, and do not define the installation mode of the lithium ion secondary battery 100 in any way.

In the present specification, the term “lithium ion secondary battery” indicates an electrical storage device that uses lithium ions as a charge carrier and realizes repetition of charge and discharge by transfer of charges of lithium ions between positive and negative electrodes.

### <Lithium Ion Secondary Battery>

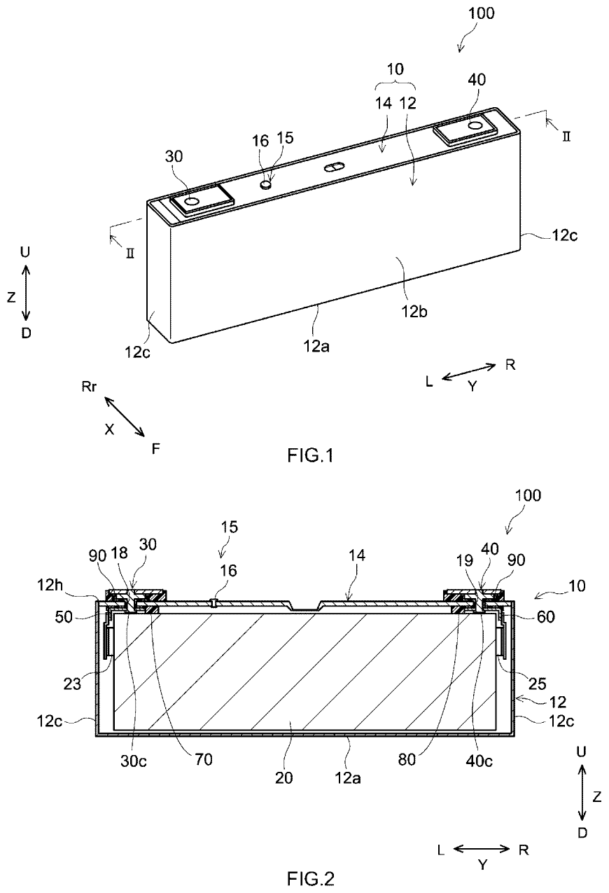

An example of a lithium ion secondary battery that is a manufacturing target of the manufacturing method disclosed here will now be described. FIG. 1 is a perspective view schematically illustrating a lithium ion secondary battery 100 according to an embodiment. FIG. 2 is a schematic longitudinal cross-sectional view taken along the line II-II in FIG. 1. The lithium ion secondary battery 100 shown in FIG. 1 or 2 includes a case 10, an electrode body 20, a positive electrode terminal 30, a negative electrode terminal 40, a positive electrode current collector 50, a negative electrode current collector 60, and a nonaqueous electrolyte (not shown). Each member will now be specifically described.

The case 10 is a housing containing the electrode body 20 and the nonaqueous electrolyte. As shown in FIG. 1, the case 10 herein has a flat bottomed rectangular parallelepiped (square) outer shape. The material of the case 10 may be the same as those conventionally used and is not particularly limited. The case 10 is preferably made of a metal such as aluminum, an aluminum alloy, iron, and an iron alloy. However, in another embodiment, the case 10 may be, for example, a bag-shaped laminate film.

As shown in FIG. 2, the case 10 includes a case main body 12 having an opening 12h and a sealing plate (lid) 14 sealing the opening 12h. The sealing plate 14 is attached to the case main body 12 so as to seal the opening 12h of the case main body 12. The case 10 is unified by that the sealing plate 14 is joined (e.g., weld joined) to the periphery of the opening 12h of the case main body 12. The case 10 is hermetically sealed (airtight sealing).

The case main body 12 includes, as shown in FIG. 1, a bottom 12a, a pair of long side walls 12b extending from the bottom 12a and facing each other, and a pair of short side walls 12c extending from the bottom 12a and facing each other. The bottom 12a has an almost rectangular shape. The bottom 12a faces the opening 12h. The long side walls 12b are each flat. The long side wall 12b extends from the long side of the bottom 12a. The short side wall 12c extends from the short side of the bottom 12a. In a planar view, the area of the long side wall 12b is larger than the area of the short side wall 12c.

The sealing plate 14 is, as shown in FIG. 2, provided with a liquid injection hole 15 and two terminal extraction holes 18, 19. The liquid injection hole 15 is that for injecting a nonaqueous electrolyte into the case 10 after attaching the sealing plate 14 to the case main body 12. The sealing plate 14 is preferably provided with the liquid injection hole 15. The liquid injection hole 15 is sealed with a sealing member 16. The terminal extraction holes 18, 19 are formed respectively on both ends (left and right ends in FIG. 2) in the long side direction Y of the sealing plate 14. The terminal extraction holes 18, 19 pass through the sealing plate 14 in the thickness direction (vertical direction Z).

As shown in FIG. 2, the positive electrode terminal 30 and the negative electrode terminal 40 are inserted into the terminal extraction holes 18, 19 and extend from the inside to the outside of the sealing plate 14. Here, the positive electrode terminal 30 and the negative electrode terminal 40 are caulked in the peripheral portion surrounding the terminal extraction holes 18, 19 of the sealing plate 14 by caulking processing. Caulking portions 30c, 40c are formed at the ends of the positive electrode terminal 30 and the negative electrode terminal 40 on the case main body 12 side (the lower end in FIG. 2).

The positive electrode terminal 30 is electrically connected to a positive electrode tab group 23 of the electrode body 20 through the positive electrode current collector 50 inside the case 10. The positive electrode terminal 30 is insulated from the sealing plate 14 by a positive electrode insulating member 70 and a gasket 90. The positive electrode terminal 30 is preferably made of a metal and more preferably, for example, aluminum or an aluminum alloy. The negative electrode terminal 40 is electrically connected to a negative electrode tab group 25 of the electrode body 20 through the negative electrode current collector 60 inside the case 10. The negative electrode terminal 40 is insulated from the sealing plate 14 by a negative electrode insulating member 80 and a gasket 90. The negative electrode terminal 40 is preferably made of a metal and more preferably, for example, copper or a copper alloy.

The electrode body 20 is accommodated in, as shown in FIG. 2, the inside of the case 10 (in detail, the inside of the case main body 12). The number of the electrode bodies 20 that are disposed inside one case 10 is not particularly limited and may be one or two or more (multiple).

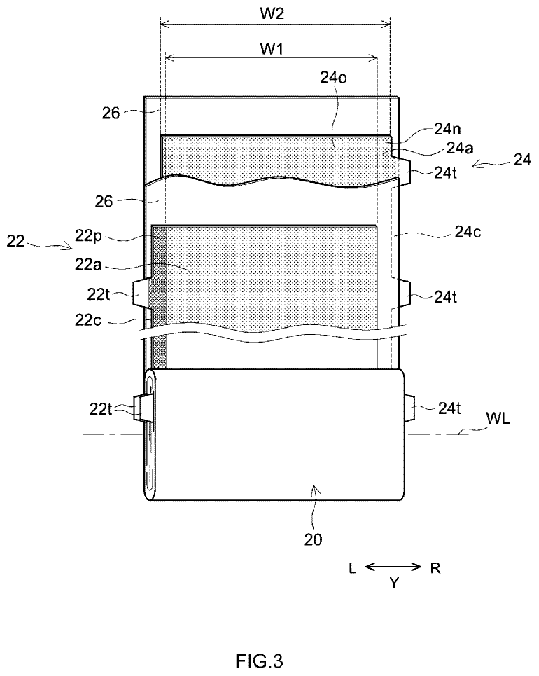

FIG. 3 is a schematic view illustrating a structure of an electrode body 20 according to an embodiment. As shown in FIG. 3, the electrode body 20 includes a positive electrode 22, a negative electrode 24, and a separator 26. The electrode body 20 herein is a flat wound electrode body. The electrode body 20 has a structure in which a stack of a belt-shaped positive electrode 22 and a belt-shaped negative electrode 24 are laminated with a belt-shaped separator 26 therebetween and are wound around a winding axis WL. However, the electrode body 20 may be a laminated electrode body in which a square (typically rectangular) positive electrode and a square (typically rectangular) negative electrode are stacked in an insulated state.

The positive electrode 22 may be the same as a conventional one, and there are no particular limitations. The positive electrode 22 includes a positive electrode current collector 22c, a positive electrode active material layer 22a adhered to at least one surface of the positive electrode current collector 22c, and a positive electrode protective layer 22p. However, the positive electrode protective layer 22p is not indispensable and may be omitted in another embodiment. The positive electrode current collector 22c is belt-shaped. The positive electrode current collector 22c is made of, for example, a conductive metal such as aluminum, an aluminum alloy, nickel, and stainless steel. The positive electrode current collector 22c herein is metal foil, specifically, aluminum foil.

A plurality of positive electrode tabs 22t is provided at one end (the left end in FIG. 3) in the long side direction Y of the positive electrode current collector 22c. The positive electrode tab 22t herein is a part of the positive electrode current collector 22c and is made of metal foil (aluminum foil). The positive electrode tabs 22t are stacked at one end (the left end in FIG. 3) in the long side direction Y and form a positive electrode tab group 23 as shown in FIG. 2. The positive electrode tab group 23 is attached (in detail, joined) with a positive electrode current collector 50. The positive electrode tab group 23 is electrically connected to the positive electrode terminal 30 through the positive electrode current collector 50.

The positive electrode active material layer 22a is provided in a belt shape along the longitudinal direction of the belt-shaped positive electrode current collector 22c. The positive electrode active material layer 22a contains a positive electrode active material that can reversibly occlude and release a charge carrier. Examples of the positive electrode active material include a lithium transition metal composite oxide such as a lithium nickel cobalt manganese composite oxide.

The positive electrode active material layer 22a may contain an optional component other than the positive electrode active material, for example, a binder, a conductive material, and various additive components. As the binder, for example, polyvinylidene fluoride (PVDF) can be suitably used. As the conductive material, for example, a carbon material such as acetylene black (AB) can be suitably used.

The positive electrode protective layer 22p is provided between the positive electrode current collector 22c and the positive electrode active material layer 22a in the long side direction Y. The positive electrode protective layer 22p is provided in a belt shape along the positive electrode active material layer 22a. The positive electrode protective layer 22p contains an inorganic filler (for example, alumina). The positive electrode protective layer 22p may contain an optional component other than the inorganic filler, for example, a conductive material, a binder, and various additive components. The conductive material and the binder may be the same as those exemplified as those that can be contained in the positive electrode active material layer 22a.

The negative electrode 24 includes a negative electrode current collector 24c and a negative electrode active material layer 24a adhered to at least one surface of the negative electrode current collector 24c. The negative electrode current collector 24c is belt-shaped. The negative electrode current collector 24c is made of, for example, a conductive metal, such as copper, a copper alloy, nickel, and stainless steel. The negative electrode current collector 24c herein is metal foil, specifically, copper foil.

A plurality of negative electrode tabs 24t is provided at one end (the right end in FIG. 3) in the long side direction Y of the negative electrode current collector 24c. The negative electrode tab 24t herein is a part of the negative electrode current collector 24c and is made of metal foil (copper foil). The negative electrode tabs 24t are stacked at one end (the right end in FIG. 3) in the long side direction Y and form a negative electrode tab group 25 as shown in FIG. 2. The negative electrode tab group 25 is attached (in detail, joined) with a negative electrode current collector 60. The negative electrode tab group 25 is electrically connected to the negative electrode terminal 40 through the negative electrode current collector 60.

The negative electrode active material layer 24a is provided in a belt shape along the longitudinal direction of the belt-shaped negative electrode current collector 24c. The negative electrode active material layer 24a contains a negative electrode active material that can reversibly occlude and release a charge carrier. Examples of the negative electrode active material include a carbon material such as graphite and a Si-containing material including silicon.

The negative electrode active material layer 24a may contain an optional component other than the negative electrode active material, for example, a binder, a dispersant, a conductive material, and various additive components. As the binder, for example, rubber such as styrene butadiene rubber (SBR) or an acrylic resin such as polyacrylic acid (PAA) can be suitably used. As the dispersant, for example, a cellulose such as carboxymethyl cellulose (CMC) can be suitably used. As the conductive material, for example, a carbon material such as a carbon fiber and a carbon nanotube can be suitably used.

The negative to positive electrode capacity ratio (negative electrode capacity/positive electrode capacity) of the electrode body 20 is, but not limited to, preferably 1.0 or more, preferably 1.025 or more, and more preferably 1.05 or more. Consequently, it is possible to more suitably suppress the precipitation of lithium metal during charging. In contrast, from the viewpoint of increasing the capacity of the lithium ion battery, the negative to positive electrode capacity ratio of the electrode body 20 is preferably 1.6 or less, preferably 1.3 or less, more preferably 1.1 or less, and further preferably 1.075 or less. In the present specification, the “negative to positive electrode capacity ratio” can be calculated by an equation: negative to positive electrode capacity ratio=(negative electrode capacity)/(positive electrode capacity) from the separately determined positive electrode capacity and negative electrode capacity. Here, the negative to positive electrode capacity ratio can be easily adjusted by, for example, modifying the weight per area of the positive and negative electrodes or changing the types of the positive and negative electrode active materials. The “weight per area” refers to the value obtained by dividing the mass of an electrode active material layer by the area of the formation region ((mass of electrode active material layer)/(area of formation region)). The positive electrode capacity can be determined as a capacity (i.e., initial positive electrode charge capacity), for example, when a half cell with Li metal as the counter electrode is produced and is initially charged in a voltage range corresponding to that of a full cell (for example, about 2 to 4.2 V). The negative electrode capacity can be determined by, for example, summing the initial negative electrode discharge capacity and the negative electrode operating voltage range.

As shown in FIG. 3, herein, the width W2 of the negative electrode active material layer 24a is greater than the width W1 of the positive electrode active material layer 22a. In other words, the negative electrode 24 in this embodiment includes a facing region 240 facing the positive electrode 22 and a non-facing region 24n not facing the positive electrode 22. Consequently, the capacity of the negative electrode 24 can be greater than the capacity of the positive electrode 22 (in other words, the negative to positive electrode capacity ratio is greater than 1.0) as the entire surface of the negative electrode. Consequently, precipitation of lithium metal during charging can be more suitably suppressed.

The separator 26 is a member for insulating between the positive electrode active material layer 22a of the positive electrode 22 and the negative electrode active material layer 24a of the negative electrode 24. The separator 26 may be the same as a conventional one, and there are no particular limitations. The separator 26 is preferably, for example, a resin porous sheet formed of a polyolefin resin such as polyethylene (PE) and polypropylene (PP). The separator 26 may include a heat resistance layer (HRL) or an adhesion layer on the surface of a base material part consisting of a resin porous sheet. The heat resistance layer and the adhesion layer may be the same as a conventional one.

The nonaqueous electrolyte may be the same as a conventional one, and there are no particular limitations. The nonaqueous electrolyte is a liquid nonaqueous electrolyte typically containing a nonaqueous solvent (organic solvent) and a supporting salt (electrolyte salt). Examples of the nonaqueous solvent include cyclic carbonates such as ethylene carbonate (EC) and monofluoroethylene carbonate (FEC) and linear carbonates such as dimethyl carbonate (DMC) and ethyl methyl carbonate (EMC). Examples of the supporting salt include lithium salts such as lithium hexafluorophosphate (LiPF₆) and sodium salts. The nonaqueous electrolyte may further contain an additive such as a coat forming agent. In another embodiment, the nonaqueous electrolyte may be in a solid or gel form.

### <Method for Manufacturing Lithium Ion Secondary Battery>

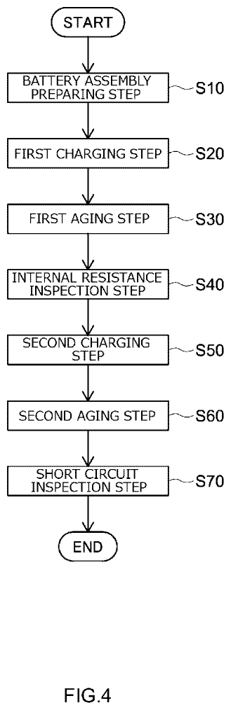

A method for manufacturing a lithium ion secondary battery disclosed here will now be described. The method for manufacturing a lithium ion secondary battery disclosed here is characterized by including a battery assembly preparing step, a first charging step, a first aging step, and a second charging step. The method for manufacturing an electrical storage device disclosed here may further include another step at an arbitrary stage in addition to the above-mentioned steps. FIG. 4 is a flow diagram of a method for manufacturing a lithium ion secondary battery 100 according to an embodiment. As shown in FIG. 4, the manufacturing method according to the present embodiment includes a battery assembly preparing step S10, a first charging step S20, a first aging step S30, an internal resistance inspection step S40, a second charging step S50, a second aging step S60, and a short circuit inspection step S70.

### (Battery Assembly Preparing Step S10)

The battery assembly preparing step S10 is a step for preparing a battery assembly including a case 10 containing an electrode body 20 and a nonaqueous electrolyte. In the present embodiment, this step includes an electrode body preparing step S12, an electrode body accommodating step S14, and a liquid injecting step S16 in this order. However, the order of the electrode body accommodating step S14 and the liquid injecting step S16 is not particularly limited. When the nonaqueous electrolyte is in a solid form (solid electrolyte), the solid electrolyte is typically unified with the electrode body 20. Accordingly, the liquid injecting step S16 can be omitted. This step may further include another step at an arbitrary stage. In the present specification, the “battery assembly” refers to all intermediate materials including the case 10, the electrode body 20, and the nonaqueous electrolyte in the manufacturing of a lithium ion secondary battery 100, and the configuration thereof is not particularly limited.

In the electrode body preparing step S12, the electrode body 20 is prepared. The electrode body 20 may be a commercially available product or may be produced by oneself. For example, when a wound electrode body is prepared as the electrode body 20, a wound electrode body can be produced by laminating the belt-shaped positive electrode 22 and the belt-shaped negative electrode 24 in an insulated state (for example, with a belt-shaped separator therebetween) and winding them. The wound electrode body can be produced by, for example, winding the belt-shaped positive electrode 22, the belt-shaped negative electrode 24, and the belt-shaped separator 26 into a roll shape around the winding axis WL using a conventionally known winding device.

In the electrode body accommodating step S14, the electrode body 20 obtained in above is accommodated in a case 10. In an example, the electrode body 20 is accommodated inside the case main body 12 through an opening 12h of the case main body 12. Subsequently, a sealing plate 14 is welded to the periphery of the opening 12h of the case main body 12 to unify the case main body 12 and the sealing plate 14.

In the liquid injecting step S16, a nonaqueous electrolyte solution is provided first as the nonaqueous electrolyte. The provided nonaqueous electrolyte solution is injected into the case 10. In one example, the prepared nonaqueous electrolyte solution is injected into the inside of the case 10 accommodating the electrode body 20 from the liquid injection hole 15 of the sealing plate 14. As in above, a battery assembly is prepared.

### (First Charging Step S20)

In the first charging step S20, the battery assembly is charged. The first charging step S20 can be performed by a known method. For example, an external power supply is connected between the positive electrode terminal 30 and the negative electrode terminal 40 of the battery assembly, and charging is performed at a constant current under predetermined temperature environment until the voltage between the terminals reaches a specified voltage. Consequently, the nonaqueous electrolyte is partially decomposed, and a SEI (solid electrolyte interface) coat is formed on the surface of the negative electrode 24 (in detail, the surface of the negative electrode active material layer 24a).

The first charging step S20 may be performed in an ordinary temperature (e.g., 25 °C±10 °C, preferably about 25 °C±5 °C) environment or may be performed in, for example, high temperature environment of about 45 °C.

From the viewpoint of forming well an SEI coat on the surface of the negative electrode 24, charging in the first charging step S20 is performed, not particularly limited, such that the SOC of the battery assembly is preferably 15% or more, more preferably 20% or more. In contrast, from the viewpoint of higher safety in the first charging step S20, charging in the first charging step S20 is performed such that the SOC of the battery assembly is 80% or less, more preferably 50% or less.

The charging rate of the first charging step S20 can be, for example, about 0.1 C to 2 C. This step may be performed by a constant current (CC) charging or may be performed by charging until a specified voltage and maintaining the voltage constantly for a predetermined time. That is, in this step, constant current-constant voltage (CCCV) charging may be performed. The charging may be performed once or can be, for example, repeated two or more times with discharging therebetween. The “1 C” means a current value that can charge the battery capacity (Ah) predicted from the theoretical capacity of the positive electrode active material in 1 hour.

It is not limited, but in the first charging step S20, charging is preferably performed in a state of restricting the case 10 of the battery assembly and applying a load thereon. Consequently, the gas generated during charging is easily excreted to the outside of the case 10. The restriction of the battery assembly can be implemented by, for example, applying a load with a specified magnitude to the long side wall 12b of the case main body 12 along the short side direction X. The load that is applied to the case 10 is not particularly limited, but can be about from 3 k N to 25 KN and is preferably 15 to 23 kN. In some embodiments, the steps after the first charging step S20 (from the first aging step S30 to the short circuit inspection step S70) may be performed while restricting the case 10 of the battery assembly and applying a load thereto. In other words, in some embodiments, multiple steps including the first charging step S20 can be performed in a state of restricting the case 10 of the assembly and applying a load thereon.

In the present embodiment, in the first charging step S20, the liquid injection hole 15 of the sealing plate 14 is open. After the completion of the first charging step S20 (in other words, before the start of the first aging step S30), the liquid injection hole 15 is sealed with the sealing member 16. Consequently, the case 10 is hermetically sealed (airtight sealing).

### (First Aging Step S30)

In the first aging step S30, the battery assembly is subjected to aging treatment. Consequently, the SEI coat of the negative electrode surface 24s is modified. The first aging step S30 can be implemented by, for example, placing the battery assembly in a thermostat or the like set to maintain a specified temperature.

The aging temperature in the first aging step S30 is not particularly limited, but is preferably 40 °C or more, more preferably 50 °C or more, and further preferably 55 °C or more, from the viewpoint accelerating the modification of the SEI coat. In contrast, from the viewpoint of suitably modifying the SEI coat, the aging temperature in the first aging step S30 is preferably 85 °C or less, more preferably 80 °C or less, and further preferably 75 °C or less.

The aging period of time in the first aging step S30 also depends on the aging temperature and the size of the battery and cannot be said definitely, but is preferably 5 hours or more and more preferably 10 hours or more. From the viewpoint of increasing the efficiency, the aging period of time is, for example, preferably 120 hours or less and preferably 72 hours or less. During this step, it is preferable that the battery assembly maintains the voltage reached in the first charging step S20.

### (Internal Resistance Inspection Step S40)

In the internal resistance inspection step S40, the internal resistance (IV resistance) of the battery assembly after the first aging step S30 is inspected. It is not limited, but in some suitable embodiments, it is preferable to perform the internal resistance inspection step S40. Consequently, the internal resistance characteristics of the battery assembly can be verified. The inspection method in the internal resistance inspection step S40 is not particularly limited, and conventionally known inspection method and apparatus can be adopted. For example, a battery assembly after the first aging step S30 is discharged at a constant current for 10 seconds from a specified value (e.g., 15% or more and less than 80%) of the SOC of the battery assembly in a specified temperature (e.g., 25 °C) environment. The internal resistance (IV resistance) can be determined by dividing the voltage drop amount ΔV during 0.1 to 10 seconds on this occasion by the current value I. The constant current value on this occasion is preferably 1 C or more.

### (Second Charging Step S50)

In the second charging step S50, the battery assembly after the first aging step S30 is charged until the state of charge (SOC) of the battery assembly reaches 100%. The second charging step is characterized in that the battery assembly is charged such that the Li saturation degree of the negative electrode surface 24s is 0.98 or less. FIG. 5 is a diagram schematically illustrating transfer of lithium ions in the negative electrode of a battery assembly. In FIG. 5, as shown by the legend, the Li saturation degree of the negative electrode active material layer 24a is shown by shading. In FIG. 5, the division of the negative electrode active material layer 24a is indicated by a dashed line. Regarding “the Li saturation degree of the negative electrode surface” in the present specification, the negative electrode active material layer 24a is divided into 20 parts in the thickness t direction of the negative electrode active material layer 24a. On this occasion, the region of the most superficial layer (in other words, the region from the surface to t/20 of the negative electrode active material layer 24a viewed from the thickness direction of the negative electrode 24) (see FIG. 5) is defined as the negative electrode surface 24s. The Li saturation degree shows the degree of charging of the region (here, the negative electrode surface 24s). For example, in the negative electrode surface 24s, the state of the negative electrode surface 24s charged to 100% can be defined as “the Li saturation degree of the negative electrode surface 24s is 1”, the uncharged (0%) state can be defined as “the Li saturation degree of the negative electrode surface 24s is 0”. That is, “the Li saturation degree of the negative electrode surface 24s is 0.98 or less” means that the state of charge of the negative electrode surface 24s is 98% or less.

In the manufacturing of the lithium ion secondary battery, from the viewpoint of the production efficiency, it is required to shorten the time of the charging step by charging the battery assembly at a large current (high rate). However, in charging (full charge) of the battery assembly until its SOC reaches 100% at the first time, the volume expansion of the negative electrode active material due to occlusion of lithium ions is likely to occur. Accordingly, in the full charge at the first time, when the charging is performed at a high rate, a crack or peeling may tend to occur in the negative electrode material by the volume expansion of the negative electrode active material. Consequently, a new surface of the negative electrode active material is generated. Such a new surface is in a high-resistance state due to insufficient formation of an SEI coat. Consequently, the lithium ion-accepting properties are deteriorated, not all lithium ions are occluded, and lithium ions may precipitate on the surface of the negative electrode active material layer as lithium metal.

Regarding this issue, the present inventors have focused on the new surface of the negative electrode active material generated during full charging at the first time and have conducted research. Consequently, the present inventors have found that when a battery assembly is charged such that the Li saturation degree of the negative electrode surface exceeds 0.98, a new surface of the negative electrode active material is generated by the volume expansion of the negative electrode active material. As a result of intensive research by the present inventors, a manufacturing method according to the present disclosure has been accomplished.

In the second charging step S50, the battery assembly is charged such that the Li saturation degree of the negative electrode surface 24s is 0.98 or less (preferably, 0.97 or less and more preferably 0.96 or less). The volume expansion of the negative electrode active material can be suitably controlled by controlling the Li saturation degree of the negative electrode surface 24s in the above range, and generation of a new surface of the negative electrode active material can be prevented. Consequently, precipitation of lithium metal on the surface of the negative electrode active material layer can be suppressed. In contrast, it is not limited, but from the viewpoint of the production efficiency, the battery assembly is preferably charged such that the Li saturation degree of the negative electrode surface 24s is 0.9 or more (more preferably 0.95 or more).

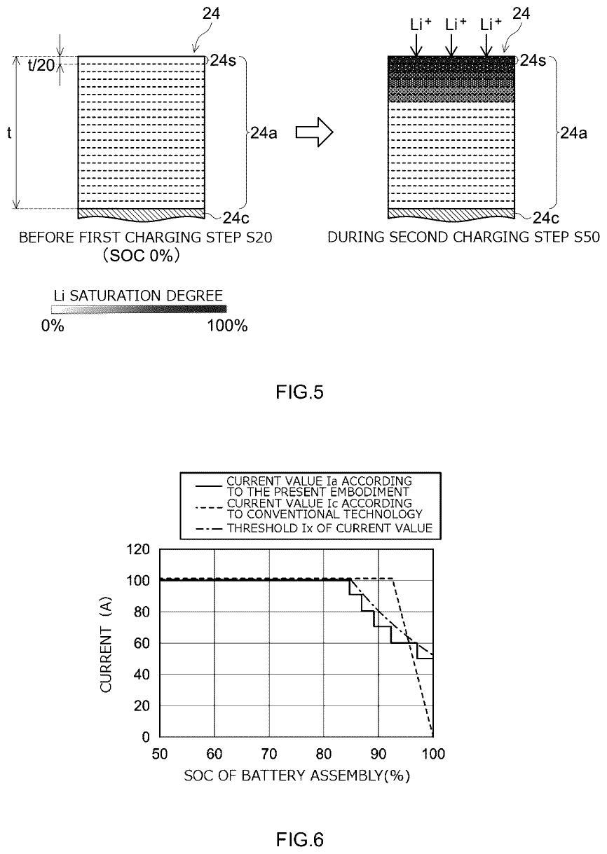

Examples of the method for charging such that the Li saturation degree of the negative electrode surface 24s is 0.98 or less include the following method (first embodiment). The method of the second charging step S50 according to the present disclosure is not limited to the following method. FIG. 6 is a graph showing the SOC (50% to 100%) of the battery assembly in the second charging step S50 and changes in the current value during charging, according to a first embodiment. FIG. 6 shows the threshold Ix of the current value at which the Li saturation degree of the negative electrode surface 24s is 0.98 (hereinafter, also simply referred to as “threshold Ix of the current value”), the current value Ic according to a conventional technology, and changes in the current value Ia according to the present embodiment.

As shown in FIG. 5, during charging of the battery assembly, lithium ions (Li⁺) are received from the surface of the negative electrode active material layer 24a (the surface on the negative electrode surface 24s side) and occluded in the negative electrode surface 24s. The occluded lithium ions are diffused inside the negative electrode active material layer 24a from the negative electrode surface 24s. In high-rate charging, the occlusion speed of lithium ions can exceed the diffusion speed. Accordingly, during high-rate charging, in the negative electrode active material layer 24a, the Li saturation degree in the negative electrode surface 24s is higher than the Li saturation degree in other region. The Li saturation degree of the negative electrode surface 24s increases with an increase in the SOC of the battery assembly, but the diffusion of the lithium ion cannot keep up with the occlusion speed. Consequently, as shown in FIG. 6, in the second charging step S50, when the Li saturation degree of the negative electrode surface 24s reaches 0.98 (SOC), the threshold Ix of the current value at which the Li saturation degree of the negative electrode surface 24s becomes 0.98 decreases. In contrast, as in the current value Ic according to a conventional technology, when the current value is maintained without considering the threshold Ix of the current value, the battery assembly can be charged at a current value Ic exceeding the threshold Ix. Accordingly, the Li saturation degree of the negative electrode surface 24s exceeds 0.98, a new surface of the negative electrode active material is generated, and eventually. lithium metal may precipitate on the surface of the negative electrode active material layer 24a.

Accordingly, in some suitable embodiments, as shown in FIG. 6, with an increase in the SOC of the battery assembly (in other words, with the progress of charging of the battery assembly), the battery assembly can be charged while stepwise decreasing the current value Ia. In other words, the battery assembly can be charged while stepwise decreasing (controlling) the current value Ia such that the current value does not exceed the threshold Ix of the current value at which the Li saturation degree of the negative electrode surface 24s becomes 0.98. Consequently, the battery assembly can be charged such that the Li saturation degree of the negative electrode surface 24s is 0.98 or less. The current value Ia may be stepwise decreased in two or more stages or in three or more stages. The number of the stages for decreasing the current value Ia can be, for example, 10 stages or less.

The “threshold Ix of the current value at which the Li saturation degree becomes 0.98” can be determined by, for example, simulation. The simulation can be performed by the method described in Japanese Patent Publication No. 2021-125423. For example, the design values of the lithium ion secondary battery 100 as a manufacturing target (e.g., the areas of coating portions of a positive electrode active material layer and a negative electrode active material layer, positive and negative electrode terminal resistances, exchange current density, and diffusion coefficient of lithium ions) are input, and lithium ion balance at Δt (t: time), and the positive and negative electrode potential are simulated. Based on the simulation, the threshold Ix of a current value at which the Li saturation degree becomes 0.98 can be calculated and determined.

It is not limited, but in the first embodiment, the battery assembly is charged by multiple stages (phases) based on the threshold Ix of the current value at which the Li saturation degree becomes 0.98 calculated in the above simulation. For example, in the first stage, constant-current charging (CC charging) is performed at a predetermined current value (specified current in the first stage) until the voltage of the battery assembly reaches a predetermined voltage (specified voltage in the first stage). When the battery assembly reaches the predetermined voltage, the phase proceeds to the subsequent stage to decrease the current value Ia to a predetermined current value (specified current in the second stage), and CC charging is performed at a specified current in the second stage until the voltage of the battery assembly reaches a predetermined voltage (specified voltage in the second stage). The above procedure is repeated multiple stages (6 stages in FIG. 6). In the final stage (the 6th stage in the present embodiment), CC charging is performed until the voltage of the battery assembly reaches an SOC of 98%, and the battery assembly is then subjected to constant voltage charging (CV charging) until the current reaches a predetermined termination current. Thus, the battery assembly can be charged until the SOC reaches 100% (full charge).

The current value (charging rate) at the time of starting the second charging step S50 may be higher or lower than or equivalent to the charging value in the first charging step S20. It is not limited, but from the viewpoint of shortening the charging period of time, it is preferable to charge the battery assembly at a higher current value (charging rate) before the threshold Ix of the current value starts to decrease after the second charging step S50 begins. From such a viewpoint, it is preferable to charge the battery assembly at a charging rate of 0.1 C or more (more preferably 0.5 C or more and further preferably 1 C or more) before the threshold Ix of the current value starts to decrease after the second charging step S50 begins. The upper limit of the charging rate is not particularly limited but can be, for example, 2 C or less. “Before the threshold Ix of the current value starts to decrease” in the present specification indicates the period from the start of the second charging step S50 until the Li saturation degree of the negative electrode surface 24s reaches 0.98 (preferably 0.97 and more preferably 0.96) at the first time.

### (Second Aging Step S60)

In the second aging step S60, the battery assembly after the second charging step S50 is further subjected to aging treatment. It is not limited, but in some preferable embodiments, it is preferable to perform the second aging step S60. Consequently, diffusion of lithium ions from the non-facing region 24n to the facing region 240 in the negative electrode 24 can be more accelerated. When a short circuit inspection step S70 described later is performed, the accuracy of the short circuit inspection can be more improved. The second aging step S60 can be implemented as in the first aging step S30, for example, by placing the battery assembly in a thermostat or the like set to maintain a specified temperature.

The aging temperature in the second aging step S60 is not particularly limited, but is preferably 40 °C or more, more preferably 50 °C or more, and further preferably 55 °C or more, from the viewpoint accelerating the diffusion of lithium ions. In contrast, from the viewpoint of suppressing deterioration, the aging temperature in the second aging step S60 is preferably 85 °C or less, more preferably 80 °C or less, and further preferably 75 °C or less.

The aging period of time in the second aging step S60 depends on the aging temperature and the size of the battery and cannot be said definitely, but can be, for example, about 6 to 72 hours and is preferably 12 to 48 hours and more preferably 18 to 24 hours.

### (Short Circuit Inspection Step S70)

In the short circuit inspection step S70, the battery assembly is subjected to short circuit inspection. It is not limited, but in some suitable embodiments, the battery assembly after the second charging step S50 is preferably subjected to the short circuit inspection step S70. Consequently, micro-short circuit of the battery assembly can be detected. The “battery assembly after the second charging step S50” in the present specification indicates the battery assembly already charged in the second charging step S50. Accordingly, another step may be implemented after the second charging step S50. In the present embodiment, the short circuit inspection step S70 is performed for the battery assembly subjected to the second charging step S50 and then the second aging step S60. The inspection method in the short circuit inspection step S70 is not particularly limited, and a conventionally known inspection method can be adopted. For example, the battery assembly is left to stand for a certain period of time for self-discharge, and a voltage drop amount thereby is measured. A short circuit can be inspected by checking whether or not the voltage drop amount is equal to or lower than a reference value.

As described above, a lithium ion secondary battery 100 can be suitably manufactured. According to the manufacturing method, a lithium ion secondary battery 100 in which precipitation of lithium metal on the negative electrode surface is suppressed can be provided.

A first embodiment of the manufacturing method disclosed herein has been described above. The technology disclosed herein is not limited to the above-described embodiment. For example, examples of another method for charging a battery assembly such that the Li saturation degree of the negative electrode surface 24s becomes 0.98 or less further include the following embodiment. Another embodiment of the technology disclosed herein will now be described.

### Second Embodiment

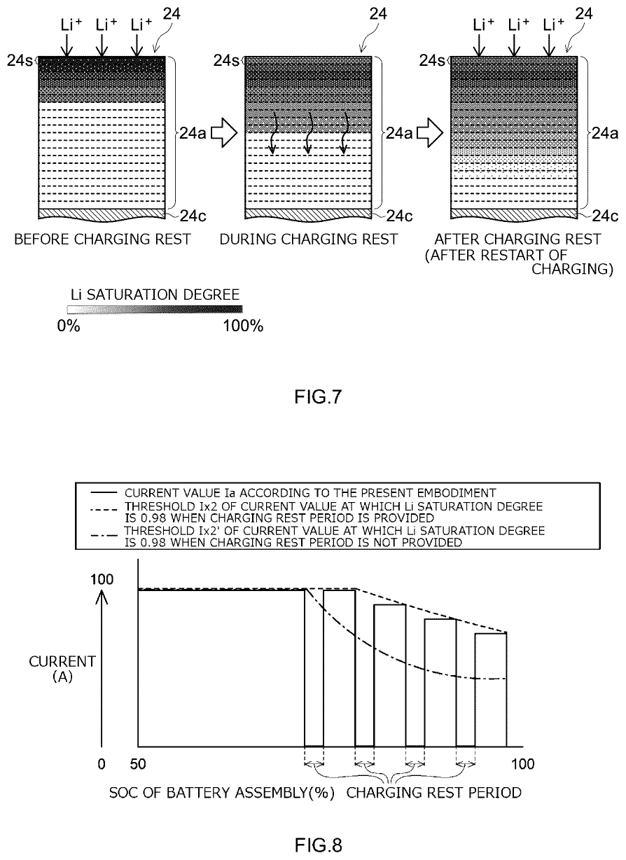

FIG. 7 is a diagram schematically illustrating transfer of lithium ions in the negative electrode of a battery assembly in the second charging step S50 according to a second embodiment. In FIG. 7, as shown by the legend, the Li saturation degree of the negative electrode active material layer 24a is shown by shading. In addition, in FIG. 7, the division of the negative electrode active material layer 24a is indicated by a dashed line. FIG. 8 is a graph showing the SOC (50% to 100%) of the battery assembly in the second charging step S50 and changes in the current value during charging, according to the second embodiment. FIG. 8 shows the threshold Ix2 of the current value at which the Li saturation degree becomes 0.98 when a charging rest period is provided (hereinafter, also referred to as “threshold Ix2 of the current value when a charging rest period is provided”) and changes in the current value Ia according to the embodiment. For reference, FIG. 8 further shows changes in threshold Ix2′ of the current value at which the Li saturation degree becomes 0.98 when the charging rest period is not provided. The manufacturing method according to the second embodiment may be the same as that in the above-described embodiment except that the charging method in the second charging step S50 is different. Accordingly, the explanation of other steps will be omitted below.

In the second embodiment, in the second charging step S50, at least one charging rest period is provided until the SOC of the battery assembly reaches 100%. In other words, in the second charging step S50 of some suitable embodiments, at least one charging rest period is preferably provided until the SOC of the battery assembly reaches 100%. In the present specification, the “charging rest period” indicates a period during which the battery assembly is neither charged nor discharged.

As described above, in the negative electrode active material layer 24a, the Li saturation degree in the negative electrode surface 24s is higher than the Li saturation degree in other regions, during the high-rate charging, Here, as shown in FIG. 7, when a charging rest period is provided, in the negative electrode 24 during the charging rest, the acceptance of lithium ions is suspended (interrupted). In contrast, the diffusion of lithium ions from the negative electrode surface 24s to the inside of the negative electrode active material layer 24a is continued. Consequently, the Li saturation degree of the negative electrode surface 24s gradually decreases compared to that before the rest in charging. Consequently, as shown in FIG. 8, the threshold Ix2 of the current value when a charging rest period is provided is higher than (recovered from) the threshold Ix2′ of the current value when a charging rest period is not provided. Accordingly, the current value Ia after the charging rest period can be set to relatively high compared to that when a charging rest period is not provided, Consequently, the period of time of the second charging step S50 can be shortened, and a lithium ion secondary battery can be manufactured more efficiently.

The method of the simulation according to the second embodiment can be the same as that in the first embodiment. In the second embodiment, the threshold Ix2 of the current value when charging rest periods are provided may be renewed by performing simulation in each charging rest period. Alternatively, in the second embodiment, the threshold Ix2 of the current value when charging rest periods are provided may be calculated by performing simulation based on charging rest periods planed in advance (the timing, the period of time, the number of times, and so on for providing the charging rest periods) may be adopted.

When a charging rest period is provided in the second charging step S50, the number of the charging rest periods may be one or multiple (two or more). It is not particularly limited, the number of the charging rest periods is preferably one or more and more preferably two or more from the viewpoint of dispersing lithium ions in the inside of the negative electrode active material layer 24a. In contrast, the number of the charging rest periods is, for example, 10 or less and preferably 8 or less.

The charging rest period (time) per one time is not particularly limited, but can be at least 0.2 minutes or more and is preferably 0.5 minutes or more and more preferably 1 minute or more, from the viewpoint of diffusing the lithium ions on the surface of the negative electrode active material layer 24a to the inside of the negative electrode active material layer 24a. In contrast, from the viewpoint of manufacturing efficiency, the charging rest period per one time is preferably 10 minutes or less and more preferably 5 minutes or less. Typically, the concentration gradient of Li ions in the thickness direction of the negative electrode active material layer decreases with an increase in the SOC of the battery assembly. Accordingly, the decreasing speed of the Li saturation degree of the negative electrode surface 24s due to the rest in charging becomes slower with an increase in the SOC of the battery assembly. Accordingly, the charging rest period per one time may be set to be longer with an increase in the SOC of the battery assembly.

The current value Ia after the rest of charging may be the same as that before the rest of charging or may be set to be lower than that before the rest of charging as long as it does not exceed the threshold Ix2 of the current valuer when the charging rest period is provided. As described above, the decreasing speed of the Li saturation degree of the negative electrode surface 24s due to the rest of charging becomes slower with an increase in the SOC of the battery assembly. From the viewpoint of shortening the charging rest period, it is preferable to charge the battery assembly while decreasing the current value Ia at the time of stepwise charging with an increase in the SOC of the battery assembly.

The lithium ion secondary battery obtained by the manufacturing method disclosed herein can be used in various uses and can be suitably used, for example, as a power source (driving power source) for motors installed in vehicles such as a passenger car and a truck. The type of the vehicle is not particularly limited, but examples thereof include a plug-in hybrid electric vehicle (PHEV), a hybrid electric vehicle (HEV), a battery electric vehicle (BEV). The lithium ion secondary battery obtained by the manufacturing method disclosed herein can also be suitably used in construction of a battery pack.

### TEST EXAMPLE

Test example relating to the technology disclosed herein will now be described, but the following test examples do not intend to limit the technology disclosed herein.

### <Battery Assembly Preparing Step>

### Example

Lithium nickel-cobalt-manganese-based composite oxide (NCM) as a positive electrode active material, polyvinylidene fluoride (PVDF) as a binder, and a carbon nanotube (CNT) as a conductive material were weighed at a mass ratio NCM:PVDF:CNT=97.5:1.5:1 and were mixed in N-methyl-2-pyrrolidone (NMP) to prepare a positive electrode slurry. This positive electrode slurry was applied to both surfaces of a long belt-shaped positive electrode current collector (aluminum foil) and was dried. The resulting product was cut into a predetermined size and was rolled with a roll press to obtain a positive electrode sheet including positive electrode active material layers on both surfaces of a positive electrode current collector.

Natural graphite (C) as a negative electrode active material, styrene-butadiene rubber (SBR) as a binder, and carboxymethyl cellulose (CMC) as a thickener were weighed at a mass ratio C:SBR:CMC=98.5:1:0.5 and were mixed in water to prepare a negative electrode slurry. This negative electrode slurry was applied to both surfaces of a long belt-shaped negative electrode current collector and was dried. The resulting product was cut into a predetermined size and was rolled with a roll press to obtain a negative electrode sheet including negative electrode active material layers on both surfaces of a negative electrode current collector.

A separator having a 3-layer structure consisting of PE/PP/PE was provided. The positive electrode sheet, the separator, and the negative electrode sheet were stacked in this order and were wound to produce a wound electrode body. The number of winding (the number of laminations) of the positive electrode sheet and the negative electrode sheet in of the wound electrode body was 35 layers.

The electrode body produced above was attached with electrode terminals and was then accommodated together with a nonaqueous electrolyte in a case. Thus, a battery assembly according to Example was prepared. The nonaqueous electrolyte used was prepared by dissolving LiPF₆ as a supporting salt at a concentration of 1.15 mol/L in a mixture solvent of ethylene carbonate (EC), dimethyl carbonate (DMC), and ethyl methyl carbonate (EMC) at a volume ratio EC:DMC:EMC=3:3:4. Thus, a battery assembly according to Example was prepared.

### <First Charging Step>

The battery assembly prepared in the battery assembly preparing step was CC charged at a 100 A (0.5 C) in an environment of 25 °C until the SOC of the battery assembly reached 80%. Herein, the steps from the first charging step to the second charging step described later were implemented in a state of restricting the case of the battery assembly and applying a constant load of 6 kN thereon. The restriction of the case of the battery assembly was continued until the short circuit inspection step.

### <First Aging Step>

The battery assembly after the first charging step was kept in an environment of 60 °C for 6 hours.

### <Internal Resistance Inspection Step>

The battery assembly after the first aging step was subjected to internal resistance inspection. Specifically, discharge was performed at a current value I of 100 A (0.5 C) for 10 seconds in an environment of 25 °C. The internal resistance (IV resistance) was calculated from the voltage drop amount ΔV (voltage difference) during 0.1 to 10 seconds and discharge current value by the following equation (I). As a result, since the internal resistance of the battery assembly according to Example was not higher than the reference value, the battery assembly passed the inspection and was subjected to the second charging step.

Internal resistance=ΔV/100 A (I).

### <Second Charging Step>

In the battery assembly of Example, the battery assembly was charged at a current value shown in the current value Ia according to the present embodiment of FIG. 6 in an environment of 25 °C. The lithium ion balance of Δt (t: time) of the battery assembly and the positive and negative electrode potentials were obtained by simulation based on the design values of the battery assembly prepared above. The simulation was performed according to the method described in Japanese Patent Publication No. 2021-125423. The threshold Ix of the current value at which the Li saturation degree becomes 0.98 was calculated based on the obtained values. The battery assembly was charged while stepwise decreasing the current value Ia during charging such that the current value Ia during charging became equal to or lower than the threshold Ix of the current value. In the present test example, the battery assembly was performed by 6 stages according to the stages (phases) 1 to 6 shown in Table 1. Specifically, in phases 1 to 5, the battery assembly was CC charged at a current value Ia shown in Table 1 until the voltage of the battery assembly reached the predetermined voltage (“Termination voltage” in Table 1). When the voltage of the battery assembly reached the predetermined voltage, the phase proceeded to the subsequent phase. In phase 6, CCCV charging performed by performing CC charging at 50 A (“Current value Ia during charging” in Table 1) until the voltage of the battery assembly reached 4.12 V (“Termination voltage” in Table 1) and then performing CV charging until the current value Ia of the battery assembly reached 5 A. Thus, the battery assembly was charged such that the Li saturation degree of the negative electrode surface was 0.98 or less.

TABLE 1

| | | Current value | | Termination |
|---|---|---|---|---|
| | Charging | Ia during | Termination | current |
| Phase | mode | charging (A) | voltage (V) | value (A) |
| 1 | CC charging | 100 | 3.98 | — |
| 2 | CC charging | 90 | 4 | — |
| 3 | CC charging | 80 | 4.02 | — |
| 4 | CC charging | 70 | 4.05 | — |
| 5 | CC charging | 60 | 4.1 | — |
| 6 | CCCV charging | 50 | 4.12 | 5 |

### <Second Aging Step>

The battery assembly after the second charging step was kept in an environment of 60 °C for 6 hours.

### <Short Circuit Inspection Step>

The battery assembly after the second aging step was subjected to short circuit inspection. Specifically, the battery assembly after the second aging step was left to stand in an environment of 25 °C for 48 hours for self-discharge. The voltage drop amount was calculated from the voltage of the battery assembly before the self-discharge and the voltage of the battery assembly after the self-discharge. As a result, since the voltage drop amount of the battery assembly according to Example was not higher than the reference value, the battery assembly passed the inspection. Thus, a battery for evaluation according to Example was prepared.

### COMPARATIVE EXAMPLE

### <From Battery Assembly Preparing Step to Internal Resistance Inspection Step>

In Comparative Example, from the battery assembly preparing step until the internal resistance inspection step were performed as in Example. That is, in Comparative Example, a battery assembly having the same configuration as that in Example was prepared, and the first charging step, the first aging step, and the internal resistance inspection step were implemented under the same conditions as in Example. As a result of the internal resistance inspection, since the internal resistance of the battery assembly according to Comparative Example was not higher than the reference value, the battery assembly passed the inspection and was subjected to the second charging step.

### <Second Charging Step>

In the battery assembly of Comparative Example, the battery assembly was charged at a current value that is shown as the current value Ic according to the conventional technology of FIG. 6. Specifically, CCCV charging was performed at 100 A (0.5 C) in an environment of 25 °C until the SOC of the battery assembly reached 100%. The charging period of time was the same as that in Example.

### <Second Aging Step and Short Circuit Inspection Step>

In Comparative Example, the battery assembly after the second charging step was subjected to the second aging step and the short circuit inspection step under the same conditions as in Example. As a result of the short circuit inspection step, since the voltage drop amount of the battery assembly according to Comparative Example was not higher than the reference value, the battery assembly passed the inspection. Thus, a battery for evaluation according to Comparative Example was prepared.

### <Evaluation Test>

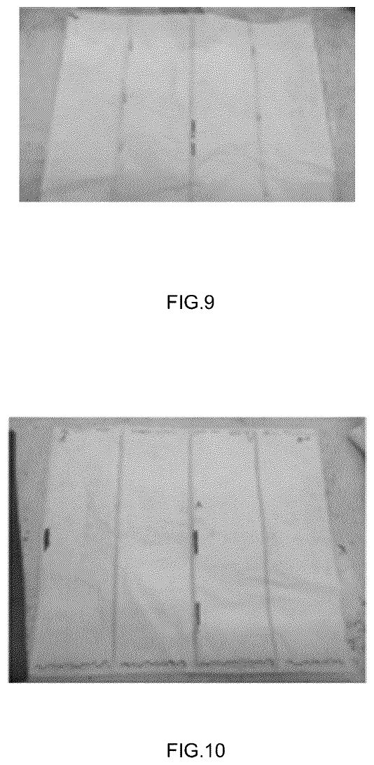

The battery for evaluation according to each Example was discharged to an SOC of 0%. After the discharge, the battery for evaluation according to each Example was disassembled, and the electrode body was taken out. The taken out electrode body was decomposed, and whether lithium metal precipitation was present or absent on the surface of the negative electrode (negative electrode active material layer) was visually verified. FIG. 9 is a photograph of the electrode body (negative electrode) showing the result of evaluation of lithium metal precipitation in Example. FIG. 10 is a photograph of the electrode body (negative electrode) showing the result of evaluation of lithium metal precipitation in Comparative Example. FIGS. 9 and 10 are captured images of surfaces of the 27th to 30th negative electrodes (negative electrode active material layers) from the outermost periphery of the electrode body of each Example.

As shown in FIG. 10, in the battery for evaluation according to Comparative Example, precipitation of lithium metal on the negative electrode surface (e.g., upper end in FIG. 10) was recognized. In contrast, in the battery for evaluation of Example, for example, as shown in FIG. 9, no precipitation of lithium metal on negative electrode surface was observed in every layer. It is believed this is because in Example, since the battery assembly was charged such that the Li saturation degree of the negative electrode surface was 0.98 or less, generation of a new surface of the negative electrode active material was suppressed.

Some embodiments of the technology disclosed herein have be described above, the embodiments are merely examples. The technology disclosed herein can be implemented in other various forms. The technology disclosed herein can be implemented based on the content disclosed in the present specification and common technical knowledge in the art. The technology described in the claims includes various modifications and changes of the above-exemplified embodiments. For example, the above-described embodiment can be partially substituted with another modified mode, or another modified mode can be added to the above-described embodiments. In addition, a technical feature that is not described to be indispensable can be appropriately omitted.

As described above, specific aspects of the technology disclosed herein include the following items.

### <Item 1>

A method for manufacturing a lithium ion secondary battery including an electrode body formed by laminating a positive electrode and a negative electrode containing a negative electrode active material with a separator therebetween and including a nonaqueous electrolyte, the method comprising:
a battery assembly preparing step of preparing a battery assembly composed of a case containing the electrode body and the nonaqueous electrolyte;
a first charging step of charging the battery assembly;
a first aging step of subjecting the battery assembly to aging treatment after the first charging step; and
a second charging step of charging the battery assembly after the first aging step until a state of charge (SOC) of the battery assembly reaches 100%,
   wherein
in the second charging step, the battery assembly is charged such that a Li saturation degree of the negative electrode surface is 0.98 or less.

### <Item 2>

The method for manufacturing a lithium ion secondary battery according to Item 1, wherein
in the second charging step, the battery assembly is charged while stepwise decreasing the current value during charging as the SOC of the battery assembly increases.

### <Item 3>

The method for manufacturing a lithium ion secondary battery according to Item 1 or 2, wherein
in the second charging step, at least one charging rest period is provided until the SOC of the battery assembly reaches 100%.

### <Item 4>

The method for manufacturing a lithium ion secondary battery according to any one of Items 1 to 3, further comprising:
an internal resistance inspection step of inspecting internal resistance of the battery assembly after the first aging step.

### <Item 5>

The method for manufacturing a lithium ion secondary battery according to any one of Items 1 to 4, further comprising:
a second aging step of further subjecting the battery assembly after the second charging step to aging treatment.

### <Item 6>

The method for manufacturing a lithium ion secondary battery according to any one of Items 1 to 5, further comprising:
a short circuit inspection step of subjecting the battery assembly after the second charging step to short circuit inspection.

### <Item 7>

The method for manufacturing a lithium ion secondary battery according to any one of Items 1 to 6, wherein
the first charging step is performed such that the SOC of the battery assembly is 15% or more and 80% or less.

### <Item 8>

The method for manufacturing a lithium ion secondary battery according to any one of Items 1 to 7, wherein
the electrode body has a negative to positive electrode capacity ratio (negative electrode capacity/positive electrode capacity) of 1.0 or more and 1.6 or less.

What is claimed is:

1. A method for manufacturing a lithium ion secondary battery comprising an electrode body formed by laminating a positive electrode and a negative electrode containing a negative electrode active material with a separator therebetween and including a nonaqueous electrolyte, the method comprising:
a battery assembly preparing step of preparing a battery assembly composed of a case containing the electrode body and the nonaqueous electrolyte;
a first charging step of charging the battery assembly;
a first aging step of subjecting the battery assembly to aging treatment after the first charging step; and
a second charging step of charging the battery assembly after the first aging step until a state of charge (SOC) of the battery assembly reaches 100%,
wherein
in the second charging step, the battery assembly is charged such that a Li saturation degree of the negative electrode surface is 0.98 or less.

2. The method for manufacturing a lithium ion secondary battery according to claim 1, wherein
in the second charging step, the battery assembly is charged while stepwise decreasing the current value during charging as the SOC of the battery assembly increases.

3. The method for manufacturing a lithium ion secondary battery according to claim 1, wherein
in the second charging step, at least one charging rest period is provided until the SOC of the battery assembly reaches 100%.

4. The method for manufacturing a lithium ion secondary battery according to claim 1, further comprising:
an internal resistance inspection step of inspecting internal resistance of the battery assembly after the first aging step.

5. The method for manufacturing a lithium ion secondary battery according to claim 1, further comprising:
a second aging step of further subjecting the battery assembly after the second charging step to aging treatment.

6. The method for manufacturing a lithium ion secondary battery according to claim 1, further comprising:
a short circuit inspection step of subjecting the battery assembly after the second charging step to short circuit inspection.

7. The method for manufacturing a lithium ion secondary battery according to claim 1, wherein
the first charging step is performed such that the SOC of the battery assembly is 15% or more and 80% or less.

8. The method for manufacturing a lithium ion secondary battery according to claim 1, wherein
the electrode body has a negative to positive electrode capacity ratio (negative electrode capacity/positive electrode capacity) of 1.0 or more and 1.6 or less.
